(19) United States
(12) Patent Application Publication
(10) Pub. No.: US 2025/0277148 A1
(43) Pub. Date: Sep. 4, 2025

(54) ORGANOCHLORIDE ETCH WITH PASSIVATION AND PROFILE CONTROL

(71) Applicant: Lam Research Corporation, Fremont, CA (US)

(72) Inventors: Ilya PISKUN, Fremont, CA (US); Gregory Clinton VEBER, Oakland, CA (US); Daksh AGARWAL, Sunnyvale, CA (US); Walter Thomas RALSTON, San Jose, CA (US); Amit MUKHOPADHYAY, Fremont, CA (US); Taner OZEL, Fremont, CA (US); Eric A. HUDSON, Berkeley, CA (US); Qing XU, Fremont, CA (US); Merrett WONG, Palo Alto, CA (US)

(21) Appl. No.: 18/859,433

(22) PCT Filed: May 3, 2023
(86) PCT No.: PCT/US2023/020847

§ 371 Date: Oct. 23, 2024

Related U.S. Application Data
(60) Provisional application No. 63/338,815, filed on May 5, 2022.

(51) Int. Cl. C09K 13/00; H01L 21/311; H01L 21/3213

(52) U.S. Cl. CPC C09K 13/00; H01L 21/31116; H01L 21/32137

(57) ABSTRACT

A method of etching recessed features in stack with a silicon containing layer below a mask and over a wafer on a substrate support is provided. An etch gas comprising a carbon source, a fluorine source, and an organochloride source selected from the group consisting of carbon tetrachloride (CCI₄), CₓH_{y}Cl_{z} (where x>0 and z>0), and combinations thereof, is provided. The etch gas is formed into a plasma. The stack is exposed to the plasma to etch recessed features into the stack.

### CROSS-REFERENCE TO RELATED APPLICATION

This application claims the benefit of priority of U.S. Application No. 63/338,815, filed May 5, 2022, which is incorporated herein by reference for all purposes.

### BACKGROUND

One process frequently employed during the fabrication of semiconductor devices is the formation of an etched cylinder or other recessed feature in a silicon containing material. The silicon containing material may be alternating/repeating layers into which the recessed feature is formed, or a thick film of a single layer of silicon-containing material. One example context where such a process may occur is memory applications such as dynamic random access memory (DRAM) and not and (NAND). As the semiconductor industry advances and device dimensions become smaller, such recessed features become increasingly harder to etch in a uniform manner, especially for high aspect ratio features having narrow widths and/or deep depths.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method of etching recessed features in a stack with a silicon containing layer below a mask and over a wafer on a substrate support is provided. An etch gas comprising a carbon source, a fluorine source, and an organochloride source selected from the group consisting of carbon tetrachloride (CCl₄), CₓH_{y}Cl_{z} (where x>0 and z>0), and combinations thereof, is provided. The etch gas is formed into a plasma. The stack is exposed to the plasma to etch recessed features into the stack.

These and other features of the present disclosure will be described in more detail below in the detailed description and in conjunction with the following figures.

### BRIEF DESCRIPTION OF THE DRAWINGS

FIG. 1 depicts a flow chart describing a method of etching recessed features into a stack containing dielectric material according to various embodiments.

FIGS. 2A-2C illustrate a reaction chamber that may be used to perform the techniques described herein according to certain embodiments.

FIG. 3 shows a semiconductor process cluster architecture that may be used to perform the techniques described herein according to certain embodiments.

FIG. 4 illustrates a computer system for implementing a controller used in embodiments of the present inventions.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Fabrication of certain semiconductor devices involves etching features into a stack of materials using plasma-based etch processes. In various embodiments herein, the stack of materials includes alternating/repeating layers of dielectric material. In a number of cases, at least one of the layers in the stack is or includes silicon containing layer. Silicon containing layers may contain silicon nitride, silicon oxide, silicon carbide, silicon oxy-nitride, silicon oxy-carbide, polysilicon, or silicon germanium. In one example, the stack includes alternating layers of silicon oxide and polysilicon. In some embodiments, the stack comprises an alternating silicon oxide film with silicon nitride films, or single silicon oxide layer, or single silicon layer.

The features etched into silicon containing materials may be cylinders, trenches, or other recessed features. The aspect ratio of such a feature is defined as the lateral critical dimension divided by the depth. As the aspect ratio of such features continues to increase, several issues arise including (1) twisting of the features, (2) non-circularity of the features, (3) aspect-ratio dependent etch rate, (4) bowing etch profile, (5) insufficient mask selectivity, and (6) low etch rate. Twisting refers to random deviations between the intended bottom locations of the features and the actual final bottom locations of the features (e.g., with the final location of a feature corresponding to the position of the bottom of the feature after the feature is etched). For instance, in some cases, it is intended that cylindrical features are etched in a regular array. When some or all features randomly deviate at the bottom away from this array, they are understood to have twisted.

Non-circularity of the features refers to deviations of the bottom hole shape away from a circular hole shape. This issue is relevant when etching circular features such as cylinders, where it is desired that the bottoms of the recessed features are circular. When the bottom hole shape deviates away from a circular shape, it often forms a shape closer to an ellipse, triangle, or irregular polygon. In many cases, these non-circular shapes are not desirable.

Aspect-ratio dependent etch rate refers to an issue where the etch rate slows down as the aspect ratio of the features increases. In other words, as the features are etched further into the dielectric material, the etching process slows down. This issue is problematic because it can lead to low throughput and associated high processing costs.

Bowing etch profile refers to the tendency for the features to etch laterally in the dielectric layer such that the final profile bows outwards excessively somewhere along the depth of the features. In other words, the actual maximum critical dimension of the features exceeds the desired maximum critical dimension of the features, which can compromise the integrity of the structures being formed or limit the electrical performance of the final devices.

Insufficient mask selectivity is problematic when the etch process removes an excessive amount of mask, such no mask remains at the end of the process, or when the amount of mask remaining is insufficient to properly transfer the pattern from the mask to the dielectric film(s). One common result of insufficient mask selectivity is the degradation of the feature profile near the top of the recessed features.

Low etch rate refers to an etch rate that is slower than desired for a particular application. Low etch rate is problematic because it leads to long etch times, reduced throughput, and high processing costs.

Unfortunately, techniques that improve some of these issues often make other issues worse. As such, these issues are balanced against one another when designing an etching operation. For example, conventional commercially practiced dielectric etch processes often result in substantial bowing. Low temperature etch processes have recently been developed to address the bowing problem associated with the conventional commercially practiced dielectric etch processes. Such low temperature processes may take place while the substrate support is cooled to a temperature of less than about 25° C. Advantageously, the low temperature processes also result in a relatively high etch rate and relatively low bowing. However, these low temperature processes substantially exacerbate issues related to twisting and non-circularity of the features. Previously, such tradeoffs have been difficult to avoid.

The techniques described herein may be used to etch recessed features into dielectric material without some or all of the issues identified above. In other words, the disclosed techniques may be used to etch recessed features into dielectric material with little or no twisting, reasonably circular features, an acceptable degree of aspect ratio dependent etch rate, acceptable bowing, sufficient mask selectivity, and sufficient etch rate.

In various embodiments herein, a particular set of reactants is used. The reactants include an organochloride source, a carbon source, and a fluorine source. Example organochloride sources include but are not limited to carbon tetrachloride (CCl₄), and hydrochlorocarbon (CₓH_{y}Cl_{z}) (where x>0 and z>0). Particular examples of CₓH_{y}Cl_{z} materials include but are not limited to, chloroform (CHCl₃), chloromethane (CH₃Cl), and methylene chloride (CH₂Cl₂). In some cases, C₂H_{y}Cl_{z} may be used. In various embodiments, the organochloride source does not include fluorine or other non-chlorine halogens.

Example carbon sources include but are not limited to, carbonyl sulfide (COS), fluorocarbon (CₓF_{y}) (where y≥x), and hydrofluorocarbon CₓH_{y}F_{z} (where z>0) or (CHₓF_{y}) (where 0<x<4, and x+y=4). Example fluorine sources include but are not limited to, CHₓF_{y} (where 0<x<4, and x+y=4), CₓF_{y} (where y≥x), CₓH_{y}F_{z} (where z>0), sulfur hexafluoride (SF₆), fluorine (F₂), phosphorus trifluoride (PF₃), and nitrogen trifluoride (NF₃). In some embodiments, the reactants may further include hydrogen sources. Example hydrogen sources include but are not limited to, hydrogen (H₂), CHₓF_{y} (where 1<x<4, and x+y=4), CₓH_{y} (such as methane (CH₄)), and CₓH_{y}F_{z}(where z>0). In some embodiments, the reactants may further include one or more non-fluorine halogen sources, examples of which include, but are not limited to, chlorine (Cl₂), hydrogen bromide (HBr), iodine (I₂), and trifluoroiodomethane (CF₃I). The organochloride source works in combination with reactants that produce abundant H radicals and F radicals, as well as the carbon source, to produce the exceptional etch results described herein.

In some embodiments, the reactants include CH₂Cl₂, H₂, NF₃, CHₓF_{y} (where 0<x<4, and x+y=4), CₓF_{y}(where y x). In some embodiments, the reactants include CH₂Cl₂, H₂, NF₃, difluoromethane (CH₂F₂), carbon tetrafluoride (CF₄), and at least one of hydrogen bromide (HBr) and trifluoroiodomethane (CF₃I). Various other combinations of reactants are possible and considered to be within the scope of the disclosed embodiments.

In some embodiments, the substrate may be maintained at a low temperature during etching. This temperature control may be accomplished by controlling the temperature of a substrate support on which the substrate is positioned during etching. In some embodiments, the substrate support may be maintained at a temperature between about −80° C. to 150° C. In certain embodiments, the substrate support is maintained at a temperature greater than 0° C. In certain embodiments, the substrate support is maintained at a temperature greater than 30° C. or greater than 60° C., or greater than 70° C. In some embodiments, the substrate support may be maintained at a temperature between about 30° C. to 150° C. At temperatures above 30° C., CD is more difficult to maintain. Some embodiments provide improved CD control at temperatures greater than 30° C.

One application for the disclosed methods is in the context of forming a vertical NAND device. In this case, the material into which the feature is etched may have a repeating layered structure. For instance, the material may include alternating layers of silicon oxide and polysilicon. The alternating layers form pairs or repeating groups of materials. In various cases, the number of pairs or repeating groups may be between about 10-500 (e.g., between about 20-1000 individual layers). The feature etched into the stack of layers may have a depth between about 2-15 μm, for example between about 5-9 μm. The feature may have a width between about 40-450 nm, for example between about 50-100 nm or between about 40-85 nm. In some embodiments, the features have a width of less than 100 nm. In some embodiments, the features have a width of less than 85 nm.

As used herein, “high aspect ratio” as applied to features in a substrate refers to height to width aspect ratios on the order of approximately 60:1 or higher. More preferably, this range may include ratios greater than 100:1, 120:1, 140:1, etc., or higher. However, the processes described herein may be beneficial for lower aspect ratios, such as 30:1, or 10:1. In some embodiments, the use of an organochloride allows for a parameter tuning that provides such narrow widths with such high aspect ratios.

There are many types of mask layers that may be used with the described embodiments, which will include any such layer known in the art which may serve as an etching mask. For example, the mask may be a carbon hard mask, such as amorphous carbon. In other embodiments, the mask may be a doped carbon.

The dimensional/parametric details provided herein, such as high, aspect ratio, thickness, width, depth, etc., are for example and illustration only. Based on the disclosure described herein, it should be understood that varying dimensions/parameters may also be applicable or used.

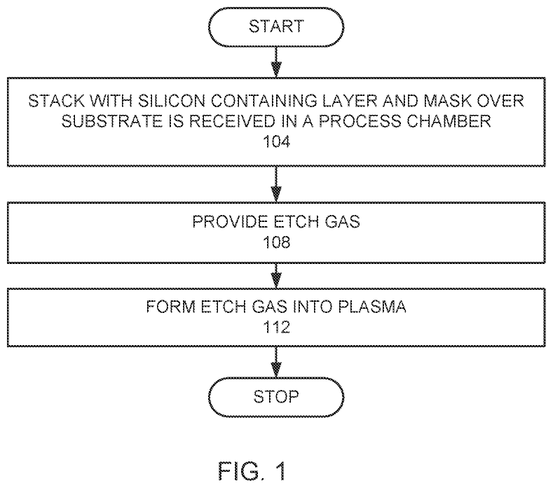

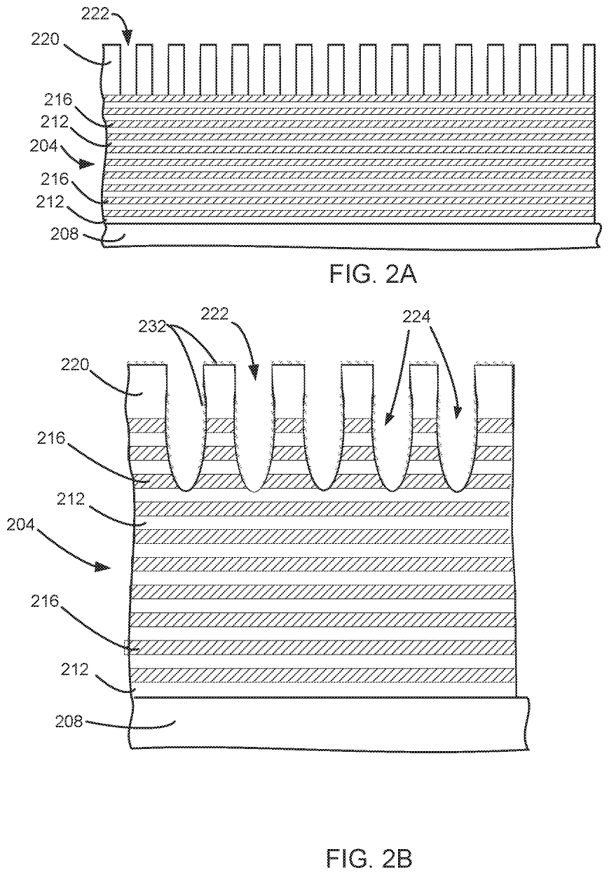

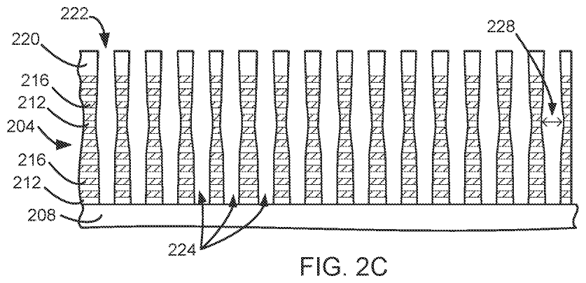

FIG. 1 is a flowchart describing a method of etching a stack according to various embodiments herein. A stack with a silicon containing layer and a mask over a substrate is received in a process chamber (step 104). FIG. 2A is a schematic cross-sectional view of a stack 204 that may be processed according to an embodiment. In this embodiment, the stack 204 may be formed over a substrate 208. One or more layers may be disposed between the stack 204 and the substrate 208. In this embodiment, the stack 204 is a plurality of bilayers of a layer of silicon oxide (SiO₂) 216 on top of a layer of polysilicon (Si) 212. A mask 220 with mask features 222 may be formed over the stack 204. In this embodiment, the mask 220 is a carbon-containing mask, such as an organic mask, one example of which would be an amorphous carbon mask. An amorphous carbon mask may also include some amount of hydrogen and/or oxygen.

Next, an etch gas is provided (step 108). The etch gas comprises components of an organochloride source, a carbon source, and a fluorine source, as described further below. The etch gas may also include a hydrogen gas source and one or more inert gases. In an example, the etch gas comprises flow rates of 1-100 sccm of (CₓH_{y}Cl_{z}) (where x>0 and z>0)(i.e. chloromethane (CH₃Cl) or dichloromethane (CH₂Cl₂)), 0-100 sccm CH₄, 10-500 sccm H₂, 5-100 sccm NF₃, 0-25 sccm CF₃I, 0-80 sccm Kr, 0-100 sccm CHₓF_{y} (where 0<x<4, and x+y=4) (i.e. fluoromethane (CH₃F), octafluorocyclobutane (C₄F₈), and CF₄), and 0-50 sccm sulfur hexafluoride (SF₆). In some embodiments, the molar flow ratio of components of an organochloride source to components of a fluorine source is in the range of 5:1 to 1:5. Additional gases may be added. Some of these gases may be removed or replaced with other gases in other embodiments. A substrate support is maintained at a temperature in a range of about −80° C. and 150° C. A chamber pressure is maintained at a pressure of about 5 to 400 millitorr (mT).

The etch gas is transformed into a plasma (step 112). In this example, a pulsed RF power is provided at different frequencies and power ranges. For example, during a first phase, RF power at 400 kilohertz (kHz) at a power in the range of 0-150° watts (W) and RF power at 60 megahertz (MHz) at a power in the range of 0-1000 W may be provided. During a second phase, RF power at 400 kHz at a power in the range of 1000-65000 W and RF power at 60 MHz at a power in the range of 500-15000 W may be provided. A pulsing duty cycle between the first phase and second phase may be in the range of 5-60%. The pulsing may be at a repetition rate in the range of 100 Hz to 20 kHz. In many cases, the plasma is a capacitively coupled plasma. The plasma in various embodiments may be generated at a radio frequency (RF) power between about 5-200 kilowatts (kW), for example between about 10-100 kW, or between about 10-65 kW in some embodiments. In some cases, dual-frequency RF may be used to generate the plasma. Thus, the RF power may be provided at two or more frequency components, for example, a first frequency component at about 400 kilohertz (kHz) and a second frequency component at about 60 megahertz (MHz). Different powers may be provided at each frequency component. For instance, the first frequency component (e.g., about 400 kHz) may be provided at a power between about 10-65 kW, and the second frequency component (e.g., about 60 MHz) may be provided at a different power, for example between about 0.5-8 kW. In some embodiments, the first frequency component (e.g., about 400 kHz) may be provided at a power higher than 65 kW. These power levels assume that the RF power is delivered to a single 300 millimeter (mm) wafer. The power levels can be scaled linearly based on substrate area for additional substrates and/or substrates of other sizes (thereby maintaining a uniform power density delivered to the substrate). In other cases, three-frequency RF power may be used to generate the plasma. In some cases, the applied RF power may be pulsed at repetition rates of 1-50,000 Hz. The RF power may be pulsed between two non-zero values (e.g., between higher power and lower power states) or between zero and a non-zero value (e.g., between off and on states). Where the RF power is pulsed between two non-zero values, the powers mentioned above may relate to the higher power state, and the lower power state may correspond to an RF power of about 4 kW or lower. The maximum ion energy at the substrate may be relatively high, for example between about 1-10 kilovolts (kV). The maximum ion energy is determined by the applied RF power in combination with the details of RF excitation frequencies, electrode sizes, electrode placement, chamber geometry, and plasma interactions.

The stack 204 is exposed to the plasma causing features to be etched into the stack. In some cases, the substrate may be exposed to the plasma for a duration between about 2000-3000 seconds (s). In some cases, the process parameters such as power, pressure, and gas flow are adjusted in a series of recipe steps. The patterned mask layer protects the underlying stack materials at positions where the patterned mask layer is present. This ensures that the recessed features are formed at the openings patterned into the mask layer, where the recessed features are desired.

FIG. 2B is a schematic cross-sectional view of the stack while etch features 224 are being etched into the stack 204 with the plasma. The presence of the organochloride and the tuning of parameters such as gas flow, pressure, RF power, and RF frequency provide a selective deposition of a chlorinated organic species deposition layer 232 on sidewalls of the etch features 224 and on the tops of the mask 220 with respect to the etch front. More specifically, the organochloride gas flow provides a robust response in improving sidewall passivation to prevent bowing. Other parameters, such as gas flow, pressure, RF power, RF frequency, RF pulsing, and temperature are tuned to provide other etch feature characteristics, where the tuning is dependent on the mask and stack or film used in a particular application.

FIG. 2C is a schematic cross-sectional view of the stack 204 after being processed according to an embodiment. In this embodiment, the plasma was able to etch through the stack 204 to the substrate 208. Bowing is indicated by the increase in the width of the features so that the width of the top of the features and the width of the bottom of the features is less than the width where there is bowing. Although this embodiment may cause some bowing, the width 228 (Bow CD) of the bowing is reduced in this embodiment. This embodiment is able to etch different silicon containing layers, such as polysilicon, silicon oxide, silicon carbide, silicon oxy-nitride, silicon oxy-carbide, and silicon nitride resulting in high aspect ratio features with reduced bowing. As used herein, CD refers to the critical dimension (e.g., width in a direction parallel to the surface of the substrate) of a feature at a particular location within the feature. The “Bow CD- Bottom CD” is defined as the difference between the maximum critical dimension width 228 of a feature and the critical dimension at the bottom of the feature. Some embodiments are able to provide a Bow CD-Bottom CD of less than 20 nm. Some embodiments provide a (Bow CD-Bottom CD)/Bow CD of less than 20%. Other metrics may use the ratio of the Bow CD/Bottom CD.

In addition, some embodiment may provide an improved selectivity. Selectivity refers to a ratio between the etch rate of the material targeted for removal and the etch rate of the mask material. This embodiment is able to selectively etch the silicon containing layer with respect to the carbon containing mask. In some embodiments, the silicon containing layer is able to be selectively etched with respect to the hardmask with a meaningful improvement in selectivity of >10% without significant tradeoff to other critical process metrics. For a stack of alternating layers of silicon oxide and polysilicon, an embodiment provides an etch selectivity ratio of the stack with respect to the etch of a carbon mask that is at least 3:1.

Ellipticity describes the degree to which the bottoms of cylindrical features deviate from a perfect circle towards an elliptical shape and is calculated as the ratio of major axis length to minor axis length for an ellipse fitted to the bottom hole shape. Features that are perfect circles have an ellipticity of 1.0. Because circular features are often desired (e.g., when etching cylinders), it is preferable for the ellipticity to be close to 1.0. In various embodiments, mask features that have a circular cross section result in features with an average ellipticity in the range of 1.0 to 1.1.

Twist refers to the degree to which the features deviate away from the desired array pattern. The twist reported herein is the standard deviation of hole-to-hole distance at the bottom of the features, multiplied by three. Because twist is not a desirable feature, it is preferable for it to be as low as possible. Some embodiments provide a twist of less than 15 nm.

### Apparatus

The various hardware and method embodiments described above may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon containing film formed thereon, using a spin-on or spray-on tool; (2) curing of photoresist using a hot plate or furnace or other suitable curing tool; (3) exposing the photoresist to visible or ultraviolet (UV) or x-ray light with a tool such as a wafer stepper; (4) developing the resist so as to selectively remove the resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The above detailed description assumes the embodiments are implemented on a wafer. However, the embodiments are not so limited. The workpiece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices, and the like.

Unless otherwise defined for a particular parameter, the terms “about” and “approximately” as used herein are intended to mean±10% with respect to a relevant value.

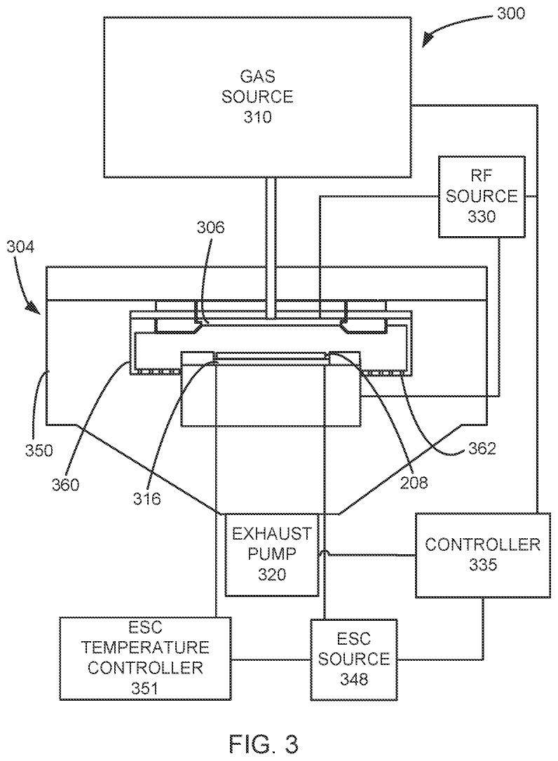

FIG. 3 is a schematic view of a plasma processing chamber 300 for plasma processing substrates, in an embodiment. In one or more embodiments, the plasma processing chamber 300 comprises a gas distribution plate 306 providing a gas inlet and an electrostatic chuck (ESC) 316, within a plasma processing chamber 304, enclosed by a chamber wall 350. Within the plasma processing chamber 304, the substrate 208 is positioned on top of the ESC 316. The ESC 316 may provide a bias from an ESC power source 348. A gas source 310 is connected to the plasma processing chamber 304 through the gas distribution plate 306. An ESC temperature controller 351 is connected to the ESC 316 and provides temperature control of the ESC 316. A radio frequency (RF) power source 330 provides RF power at RF frequencies to the ESC 316 and an upper electrode. In this embodiment, the upper electrode is the gas distribution plate 306. In a preferred embodiment, 400 kilohertz (kHz), 13.56 megahertz (MHz), 1 MHz, 2 MHz, 60 MHz, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the plasma processing chamber 304, which confines gas from the gas source and has slots 362. The slots 362 maintain a controlled flow of gas to pass from the gas source 310 to the exhaust pump 320. An example of such a plasma processing chamber is the Flex® etch system manufactured by Lam Research Corporation of Fremont, CA. The process chamber can be a CCP (capacitively coupled plasma) reactor or an ICP (inductively coupled plasma) reactor.

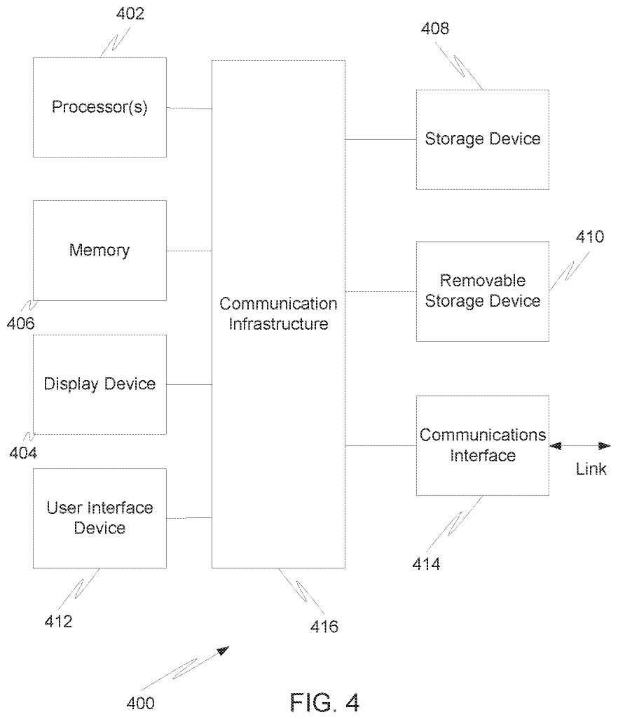

FIG. 4 is a high level block diagram illustrating a computer system 400 for implementing the controller 535 used in embodiments of the present inventions. The computer system may have many physical forms ranging from an integrated circuit, a printed circuit board, and a small handheld device up to a huge supercomputer. The computer system 400 may include one or more processors 402 and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and/or a communication interface 414 (e.g., wireless network interface). The communication interface 414 may allow software and/or data to be transferred between the computer system 400 and external devices via a link. The system may also include a communications infrastructure 416 (e.g., a communications bus, cross-over bar, or network) to which the aforementioned devices/modules may be connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that are executed by a computer using an interpreter.

Computer readable media may also be computer code transmitted by a computer data signal embodied in a carrier wave and representing a sequence of instructions that are executable by a processor.

It is to be understood that the configurations and/or approaches described herein are exemplary in nature and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. Certain references have been incorporated by reference herein. It is understood that any disclaimers or disavowals made in such references do not necessarily apply to the embodiments described herein. Similarly, any features described as necessary in such references may be omitted in the embodiments herein. The subject matter of the present disclosure includes all novel and nonobvious combinations and sub-combinations of the various processes, systems and configurations, and other features, functions, acts, and/or properties disclosed herein, as well as any and all equivalents thereof.

### CONCLUSION

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method of etching recessed features in stack with a silicon containing layer below a mask and over a wafer on a substrate support, the method comprising:
a. flowing an etch gas, comprising:
i. an organochloride source selected from the group consisting of carbon tetrachloride (CCl₄), CₓH_{y}Cl_{z} (where x>0 and z>0), and combinations thereof,
ii. a carbon source, and
iii. a fluorine source,
b. forming the etch gas into a plasma; and
c. exposing the stack to the plasma to etch recessed features into the stack.

2. The method of claim 1, wherein the stack comprises alternating layers of silicon oxide and polysilicon.

3. The method of claim 1, further comprising maintaining the substrate support at a temperature above about 30° C.

4. The method of claim 1, further comprising maintaining the substrate support at a temperature in a range of −80° C. to 150° C.

5. The method of claim 1, wherein the etch gas further comprises a hydrogen source.

6. The method, as recited in claim 5, wherein the hydrogen source comprises at least one material selected from the group consisting of H₂, CHₓF_{y} (where 1<x≤4, and x+y=4), CₓH_{y}F_{z} (where x>0 and z>0), CₓH_{y}, and combinations thereof.

7. The method of claim 5, wherein the hydrogen source comprises H₂.

8. The method of claim 1, wherein the fluorine source comprises at least one material selected from the group consisting of: NF₃, SF₆, F₂, PF₃, CHₓF_{y} (where 0<x<3, and x+y=4), CₓF_{y} (where y≥x), CₓH_{y}F_{z} (where z>0), and combinations thereof.

9. The method of claim 1, wherein the carbon source comprises at least one material selected from the group consisting of: COS, CHₓF_{y} (where 0<x≤4, and x+y=4), CₓF_{y} (where y≥x), CₓH_{y}F_{z} (where x>0 and z>0), and combinations thereof.

10. The method of claim 1, wherein the organochloride source is at least one of CHCl₃, CH₃Cl, or CH₂Cl₂.

11. The method of claim 1, wherein the silicon containing layer comprises at least one of silicon nitride, silicon oxide, silicon carbide, silicon oxy-nitride, silicon oxy-carbide, polysilicon, or silicon germanium.

12. The method of claim 1, wherein the forming the etch gas into a plasma comprises providing RF power at one or more RF frequencies to provide energy for forming the etch gas into a plasma.

13. The method of claim 12, further comprising maintaining the substrate support at a temperature above about 30° C.

14. The method of claim 1, wherein the exposing the stack to the plasma etches the features with a height to width aspect ratio greater than 100:1.

15. The method of claim 1, wherein the etch gas has a molar flow ratio of an organochloride source component to fluorine source component in a range of 5:1 to 1:5.

16. The method of claim 1, wherein the exposing the stack to the plasma causes a selective deposition of chlorinated organic species on sidewalls of the recessed features with respect to etch fronts of the recessed features.
